(19) United States
(12) Patent Application Publication
(10) Pub. No.: US 2014/0231831 A1
(43) Pub. Date: Aug. 21, 2014

(54) LED CHIP AND METHOD FOR MANUFACTURING THE SAME

(71) Applicant: Lextar Electronics Corporation, Hsinchu (TW)

(72) Inventors: PEI-SHIU TSAI, Taoyuan City (TW); Wan-Chun HUANG, Taichung City (TW)

(73) Assignee: Lextar Electronics Corporation, Hsinchu (TW)

(21) Appl. No.: 14/028,813

(22) Filed: Sep. 17, 2013

(30) Foreign Application Priority Data
Feb. 19, 2013 (TW) 102105730

(51) Int. Cl. H01L 33/02

(52) U.S. Cl. CPC H01L 33/02
USPC 257/79; 438/33

(57) ABSTRACT

The invention provides a substrate structure used for manufacturing a light-emitting diode and a method for manufacturing the light-emitting diode. The substrate structure includes a substrate having a first surface and a second surface opposite to the first surface and a plurality of grooving structure formed on the first surface of the substrate. The light-emitting diode is formed on the first surface of the substrate.

### RELATED APPLICATIONS

This application claims priority to Taiwan Application Serial Number 102105730 filed Feb. 19, 2013, which is herein incorporated by reference.

### BACKGROUND

1. Technical Field

The present disclosure relates to a light-emitting diode, and more particularly, to a light-emitting diode having a plurality of recess structures on the side walls.

2. Description of Related Art

Generally, when a light-emitting diode (LED) operates and emits light, the light travels into a transparent substrate from a light-emitting layer, and then transmits out from sidewalls of the transparent substrate. Therefore, the transmittance of the transparent substrate directly affects the light-emitting efficiency of light-emitting diode. Conventionally, a sidewall etching (SWE) process or a stealth dicing (SD) process is used to isolate LED dies, but it is known that the processes are harmful to the transmittance of a light-emitting diode.

For example, when the SWE process is used to isolate the LED dies, several sintering marks may be formed on the transparent substrate. The sintering marks can absorb light energy and reduce the transmittance. On the other hand, when the SD process is used to isolate the LED dies, the sidewall of the LED dies are so smooth that the light entering into the transparent substrate may face total internal reflection, which reduces the transmittance.

Therefore, an improved LED die and a method of manufacturing the same are needed to solve the aforementioned problems.

### SUMMARY

The present disclosure provides a light-emitting diode (LED) die and a method for manufacturing thereof, so as to solve the problems of the prior art and enhance the transparent efficiency of the LED die.

One aspect of the present disclosure is to provide an LED die. The LED die comprises a transparent substrate, an N-type semiconductor layer positioned on the transparent substrate, a light-emitting layer positioned on the N-type semiconductor layer, and a P-type semiconductor layer positioned on the light-emitting layer. In which, the N-type semiconductor layer, the transparent substrate or both have side walls with a plurality of recess structure.

Another aspect of the present disclosure is to provide a method for manufacturing the LED die. The method for manufacturing the LED die comprises the following steps. A transparent substrate is provided, which has an upper surface. A LED stacked structure is formed on the transparent substrate. A plurality of recess structures are formed on sidewalls of the N-type semiconductor layer, the transparent substrate or both. In which, the LED stacked structure comprises an N-type semiconductor layer positioned on the transparent substrate, a light-emitting layer positioned on the N-type semiconductor layer, and a P-type semiconductor layer positioned on the light-emitting layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a top view of a light-emitting diode (LED) die according to one embodiment of the present disclosure;

FIG. 1B and 1C are cross-sectional views of the LED die taken along A-A′ line in FIG. 1A;

FIG. 1D to 1F are cross-sectional views of the LED die taken along B-B′ line in FIG. 1A;

FIG. 2A is a top view of an LED die according to one embodiment of the present disclosure;

FIG. 2B is a cross-sectional view of the LED die taken along C-C′ line in FIG. 2A;

FIG. 2C and 2D are cross-sectional views of the LED die taken along D-D′ line in FIG. 2A; and

FIG. 3A to 3F are side views of LED die structures according to embodiments of the present disclosure.

### DETAILED DESCRIPTION

The light-emitting diode (LED) die and the method for manufacturing the same of the embodiments are discussed in detail below, but not limited the scope of the present disclosure. The same symbols or numbers are used to the same or similar portion in the drawings or the description. And the applications of the present disclosure are not limited by the following embodiments and examples, which the person in the art can apply in the related field.

The present disclosure provides an LED die, and a method for manufacturing thereof. In which, the LED die comprises a plurality of recess structures enhancing the laterally light-emitting efficiency of the LED die.

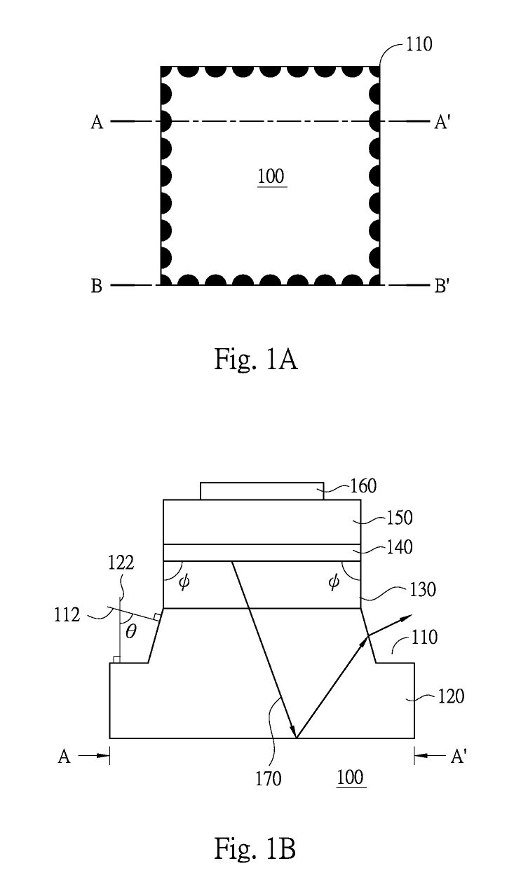

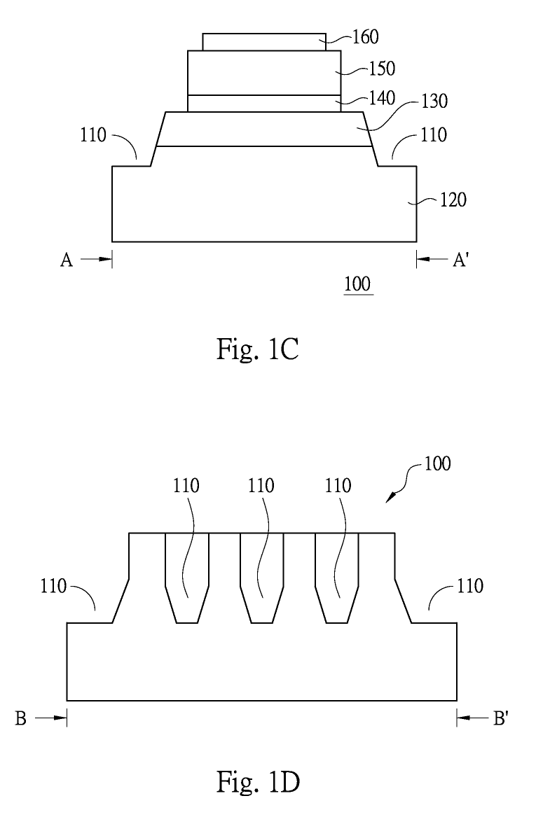

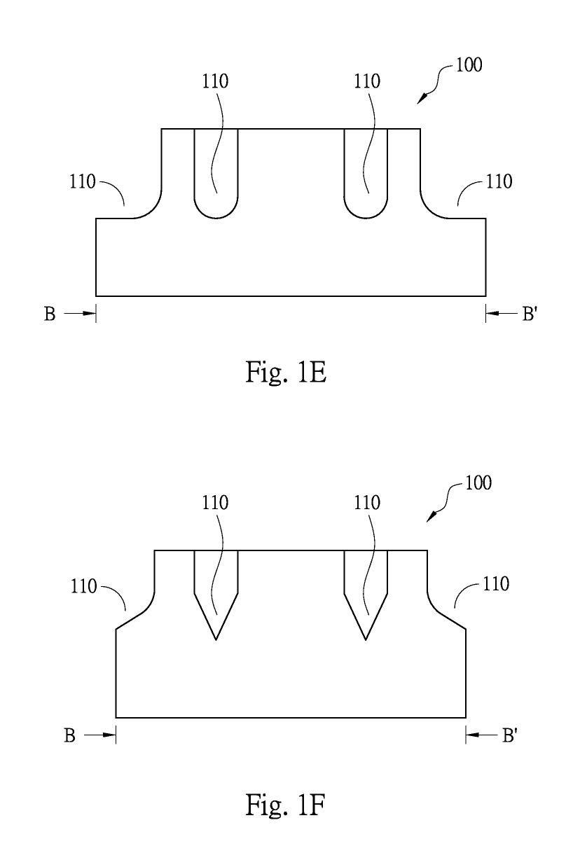

FIG. 1A is a top view of a light-emitting diode (LED) die according to one embodiment of the present disclosure. In FIG. 1A, the LED die 100 comprises a plurality of recess structures 110 surrounding the edge of the LED die 100.

FIG. 1B and 1C are cross-sectional views of the LED die taken along A-A′ line in FIG. 1A. In FIG. 1B, the structure of the LED die 100 from bottom to top is a transparent substrate 120, an N-type semiconductor layer 130, a light-emitting layer 140, a P-type semiconductor layer 150 and an electrode 160. In which, the recess structures 110 are positioned on the sidewalls of the transparent substrate 120. According to one embodiment of the present disclosure, the recess structures 110 are positioned on the sidewalls of the transparent substrate 120 and the N-type semiconductor layer 130, as shown in FIG. 1C. According to another embodiment of the present disclosure, the recess structures 110 are positioned on the sidewalls of the N-type semiconductor layer 130. According to one embodiment of the present disclosure, the material of the transparent substrate 120 is selected from the group of sapphire, silicon, silicon carbide (SiC), diamond, quartz, and the combinations thereof.

Otherwise, in FIG. 1B, the sidewalls of the transparent substrate 120 and the N-type semiconductor layer 130 further comprises a chamfer structure (φ). According to one embodiment of the present disclosure, the chamfer structure (φ) has angle in a range of 30° to 90°.

A cross-section of the recess structures 110 has a first normal line 112, and the transparent structure 120 has a second normal line 122, wherein the first normal line 112 and the second normal line 122 has an included angle (θ). According to one embodiment of the present disclosure the included angle (θ) is in a range of 30° to 60°. According to another embodiment of the present disclosure, the included angle (θ) is 45°.

The light 170 may enter into the transparent substrate 120 from the light-emitting layer 140, and then emit from the sidewalls of the transparent substrate 120. Because the recess structures 110 may be a rough surface on the edge of the transparent substrate 120 or the N-type semiconductor layer 130, and increase the surface area, the light-emitting efficiency of the LED die 100 is increased thereby.

The recess structures of the LED die are orifice-shaped, groove-shaped or both. In which, the orifice-shaped recess structures are in shape of inverted trapezoid, pullet, saw tooth, inverted pyramid, or a combination thereof.

FIGS. 1D to 1F are cross-sectional views of the LED die taken along B-B′ line in FIG. 1A. In FIG. 1D, the recess structures 110 of the LED die 100 is in inverted trapezoid shape. According to one embodiment of the present disclosure, the recess structures 110 of the LED die 100 is in pullet shape, as shown in FIG. 1E. According to another embodiment of the present disclosure, the recess structures 110 of the LED die 100 is in inverted pyramid shape, as shown in FIG. 1F. According to one embodiment of the present disclosure, the depth of the recess structures 110 is in a range of 6 μm to 12 μm.

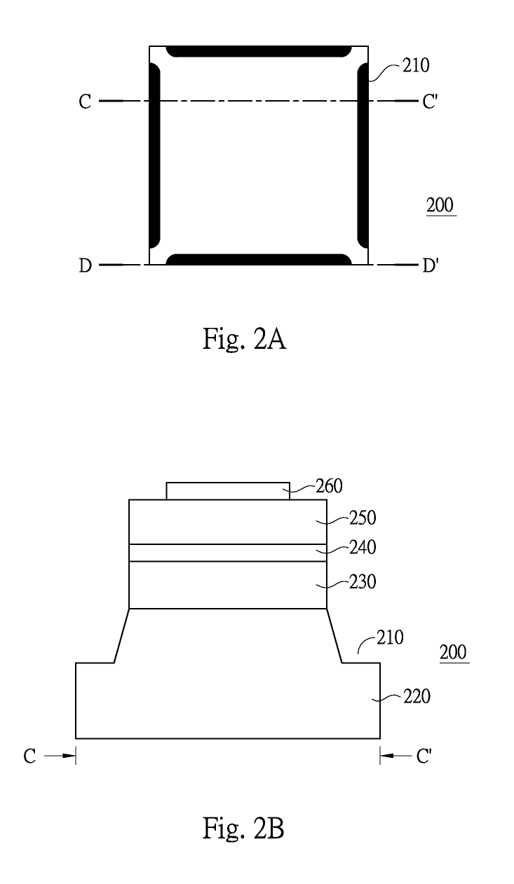

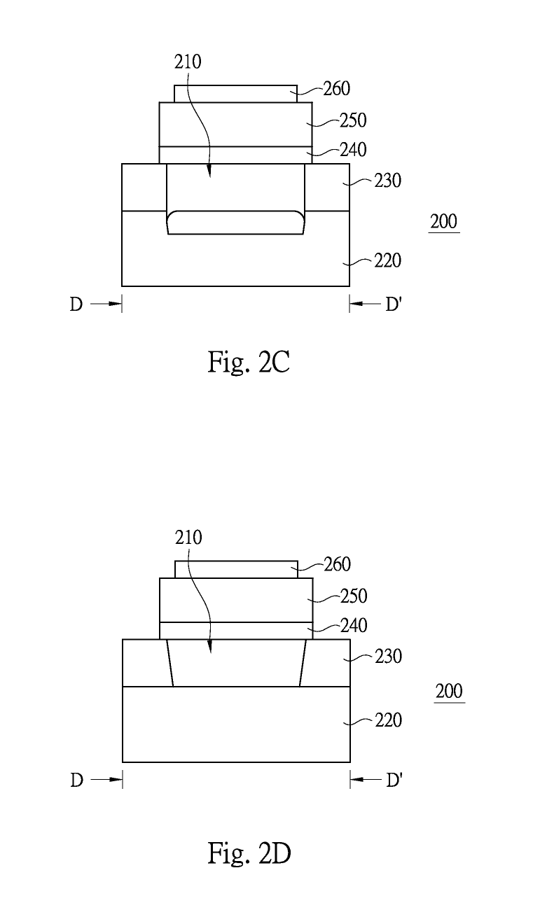

FIG. 2A is a top view of an LED die according to one embodiment of the present disclosure, wherein the recess structures is in grooves. In FIG. 2A, a LED die 200 comprises a plurality of recess structures 210 in grooves surrounding the edge of the LED die 200.

FIG. 2B is a cross-sectional view of the LED die taken along C-C′ line in FIG. 2A. In FIG. 2B, the structure of the LED die 200 from bottom to top is a transparent substrate 220, an N-type semiconductor layer 230, a light-emitting layer 240, a P-type semiconductor layer 250 and an electrode 260. In which, the recess structures 210 are positioned on the sidewalls of the transparent substrate 220.

FIGS. 2C and 2D are cross-sectional views of the LED die taken along D-D′ line in FIG. 2A. In FIG. 2C, the recess structures 210 are positioned on the sidewalls of the transparent substrate 220 and the N-type semiconductor layer 230. In FIG. 2D, the recess substrates 210 are positioned on the sidewalls of the N-type semiconductor layer 230.

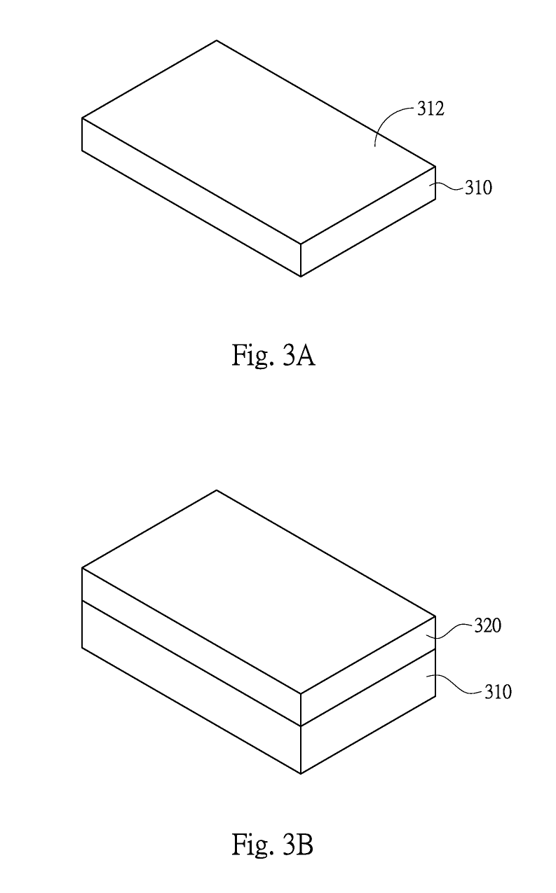

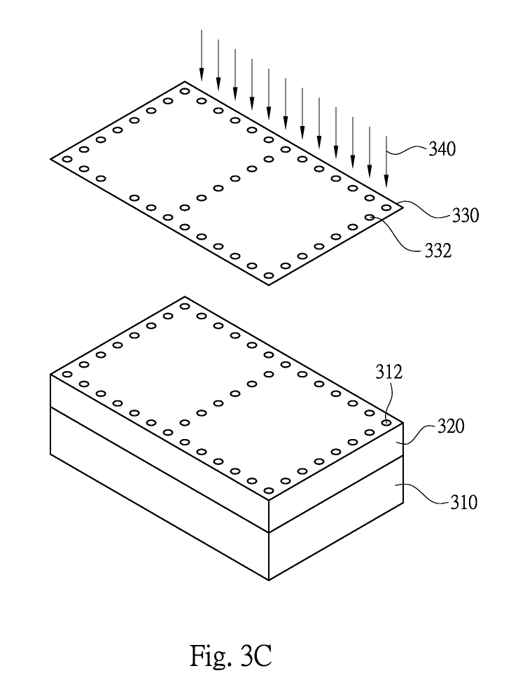

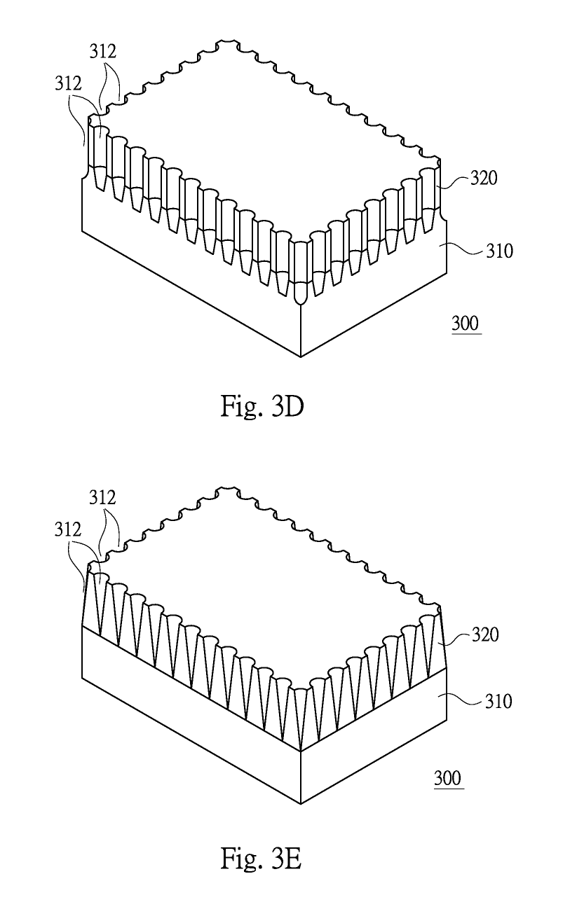

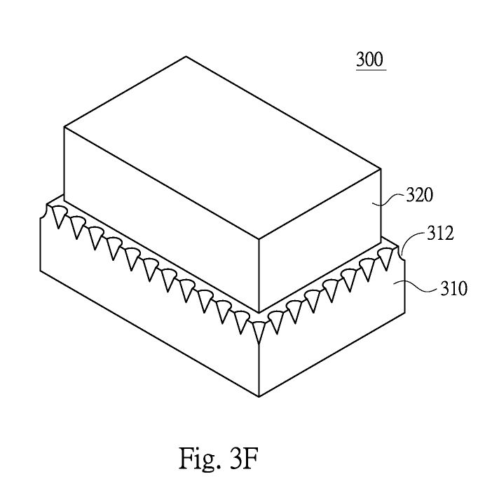

FIGS. 3A to 3F are side views of LED die structures according to embodiments of the present disclosure. In FIG. 3A, the transparent substrate 310 is provided, which has an upper surface 312. Then, a light-emitting diode (LED) structure 320 is formed on the upper surface of the transparent substrate 310, as shown in FIG. 3B. The LED stacked structure 320 from bottom to top comprises an N-type semiconductor layer, a light-emitting layer and a P-type semiconductor layer, wherein the N-type semiconductor layer, the light-emitting layer and the P-type semiconductor layer are not shown individually.

In FIG. 3C, a mask 330 has a plurality of holes 332. The mask 330 covers on the LED stacked structure 320, and then form a plurality of recess structures 312 on the transparent substrate 310, the LED stacked structure 320 or the both, by an etching method 340. In which, the etching method 340 may be a dry-etching or a wet-etching or the both.

According to one embodiment of the present disclosure, the dry-etching is performed by inductively coupled plasma (ICP). Compared to wet-etching, dry-etching possess higher accuracy, but may damage the LED stacked structure.

According to one embodiment of the present disclosure, the wet-etching is performed by hot phosphoric acid. Because hot phosphoric acid may etch the N-type semiconductor layer at the same time, the light-emitting efficiency can be enhanced. But, compared to dry-etching, the etching time of wet-etching is longer, and may damage the LED stacked structure.

According to one embodiment of the present disclosure, the recess structures are formed by laser, and then sintering marks are removed by hot phosphoric acid. Because the depth of the recess structures can be controlled precisely by laser, and the etching time can be reduced, the LED die made by this embodiment has better light-emitting efficiency.

In FIG. 3D, the LED stacked structure 320 and the transparent substrate 310 are diced along the recess structures 312, so as to form the LED die 300. In which, the recess structures 312 are formed on the sidewalls of the LED stacked structure 320 and the transparent substrate 310.

According to one embodiment of the present disclosure, the recess structures 312 are only formed on the sidewalls of the LED stacked structure 320, as shown in FIG. 3E. According to another embodiment of the present disclosure, the LED stacked structure 320 does not completely cover the transparent substrate 310, so the recess structures 312 can be only formed on the sidewalls of the transparent substrate 310, as shown in FIG. 3F.

TABLE 1

| | | Promoting | | | |
|---|---|---|---|---|---|
| | | Rate of | | | |
| | | Light | | Difference | |
| | Light | intensity | Electric | of Electric | Yield |
| | Intensity | (%) | Performance | Performance | (%) |
| Example 1 | 193.04 | 2.3% | 3.09 | −0.02 | 95.80 |
| Comparative | 188.62 | — | 3.11 | — | 94.17 |
| Example 1 | | | | | |
| Example 2 | 197.05 | 3.6% | 3.10 | 0.00 | 95.21 |
| Comparative | 190.13 | — | 3.10 | — | 95.09 |
| Example 2 | | | | | |
| Example 3 | 195.85 | 2.0% | 3.09 | −0.01 | 93.42 |
| Comparative | 192.08 | — | 3.10 | — | 91.86 |
| Example 3 | | | | | |
| Example 4 | 197.59 | 1.2% | 3.10 | −0.02 | 93.95 |
| Comparative | 195.34 | — | 3.12 | — | 93.82 |
| Example 4 | | | | | |

Table 1 is comparisons of a wet-etching method with laser and a sidewall etching method for the influence of the light intensity, electric performance and yield of LED dies. The experiment is performed on the same wafer, wherein a half of the wafer is used to make LED dies by the sidewall etching; and another half of the wafer is used to make LED dies by the wet-etching method with laser.

On Table 1, Examples 1-4 are all firstly forming recess structures by laser, and then removing residual sintering marks by hot phosphoric acid. And Comparative Examples 1-4 are only performed sidewall etching by laser. Compared to Comparative Examples, the light intensities of LED of Examples are enhanced 1.2% to 3.6%. Otherwise, there is no significant difference of electric performance and yield of LEDs between Examples and Comparative Examples. It is known as the results of Table 1 that the light intensities of LEDs provided by embodiments of the present disclosure are enhanced without the influence of the electric performance and yield of the same.

In embodiments of the present disclosure, since the recess structures are formed on the transparent substrate, the N-type semiconductor layer or the both, it can not only increase the surface area of the side wall of LEDs, but also enhance the light-emitting efficiency. Therefore, the method for manufacturing LEDs provided by embodiments of the present disclosure can solve the problems of the conventional manufacturing process.

Although embodiments of the present disclosure and their advantages have been described in detail, they are not used to limit the present disclosure. It should be understood that various changes, substitutions and alterations can be made herein without departing from the spirit and scope of the present disclosure. Therefore, the protecting scope of the present disclosure should be defined as the following claims.

What is claimed is:

1. A light-emitting diode die, comprising:
a transparent substrate;
an N-type semiconductor layer positioned on the transparent substrate;
a light-emitting layer positioned on the N-type semiconductor layer; and
a P-type semiconductor layer positioned on the light-emitting layer,
wherein the N-type semiconductor layer, the transparent layer or both have sidewalls with a plurality of recess structures.

2. The light-emitting diode die of claim 1, wherein the recess structures are orifice-shaped, groove-shaped or both.

3. The light-emitting diode die of claim 2, wherein the orifice-shaped recess structures are in shape of inverted trapezoid, pullet, saw tooth, inverted pyramid, or a combination thereof.

4. The light-emitting diode die of claim 3, wherein a cross-section of the recess structure has a first normal line, and the N-type semiconductor layer, the transparent substrate or both have a second normal line, wherein the first normal line and the second normal line has an included angel in a range of 30 to 60 degrees.

5. The light-emitting diode die of claim 4, wherein the included angle of the first normal line and the second normal line is 45 degrees.

6. The light-emitting diode die of claim 1, wherein the depth of the recess structures is in a range of 6 μm to 12 μm.

7. The light-emitting diode die of claim 1, wherein the material of the transparent substrate is selected from the group comprising of sapphire, silicon, silicon carbide (SiC), diamond, quartz and the combinations thereof.

8. The light-emitting diode die of claim 1, wherein sidewalls of the N-type semiconductor layer and the transparent substrate form a chamfer structure.

9. The light-emitting diode die of claim 8, wherein the chamfer structure has an angle in a range of 30 to 90 degrees.

10. A method for manufacturing a light-emitting diode die, comprising the steps of:
providing a transparent substrate having an upper surface;
forming a light-emitting diode stacked structure on the upper surface of the transparent substrate, wherein the light-emitting diode stacked structure comprises:
an N-type semiconductor layer positioned on the transparent substrate;
a light-emitting layer positioned on the N-type semiconductor layer; and
a P-type semiconductor layer positioned on the light-emitting layer; and
forming a plurality of recess structures on sidewalls of the N-type semiconductor layer, the transparent substrate or both.

11. The method of claim 10, further comprising the step of:
dicing the light-emitting diode stacked structure and the transparent substrate taken along the recess structures.

12. The method of claim 10, wherein the recess structures are orifice-shaped, groove-shaped or both.

13. The method of claim 12, wherein the orifice-shaped recess structures are in shape of inverted trapezoid, pullet, saw tooth, inverted pyramid, or a combination thereof.

14. The method of claim 10, wherein a cross-section of the recess structure has a first normal line, and the N-type semiconductor layer, the transparent substrate or both have a second normal line, wherein the first normal line and the second normal line has an included angle in a range of 30 to 60 degrees.

15. The method of claim 14, wherein the included angle between the first normal line and the second normal line is 45 degrees.

16. The method of claim 10, further comprising a step, wherein the depth of the recess structures is in a range of 6 μm to 12 μm.

17. The method of claim 10, wherein the material of the transparent substrate is selected from the group comprising of sapphire, silicon, silicon carbide (SiC), diamond, quartz and the combinations thereof.

18. The method of claim 10, wherein the recess structures are formed by dry etching, wet etching or laser etching.

19. The method of claim 10, wherein the sidewalls of the N-type semiconductor layer and the transparent substrate form a chamfer structure.

20. The method of claim 19, wherein the chamfer structure has angle in a range of 30 to 90 degrees.
